(19) United States
(12) Patent Application Publication
(10) Pub. No.: US 2026/0084956 A1
(43) Pub. Date: Mar. 26, 2026

(54) LOW STRESS FLIPCHIP MEMS PACKAGE

(71) Applicant: STMicroelectronics International N.V., Geneva (CH)

(72) Inventor: Jefferson Sismundo TALLEDO, Calamba (PH)

(73) Assignee: STMicroelectronics International N.V., Geneva (CH)

(21) Appl. No.: 19/310,498

(22) Filed: Aug. 26, 2025

Related U.S. Application Data
(60) Provisional application No. 63/696,965, filed on Sep. 20, 2024.

(51) Int. Cl. B81B 7/00; B81C 1/00

(52) U.S. Cl. CPC B81B 7/0048; B81C 1/00325; B81B 2207/012; B81B 2207/07; B81C 2203/0785

(57) ABSTRACT

Disclosed herein is a microelectromechanical systems (MEMS) package and its manufacturing method. The package includes a substrate with a first cavity, an interposer mounted on the substrate, a MEMS die attached to the interposer and extending into the first cavity, and a cap extending over the interposer and MEMS die. The cap, combined with the first cavity, defines a second cavity enclosing the MEMS die, allowing it to float within a gas or near-vacuum environment. An Application-Specific Integrated Circuit (ASIC) is mounted on the substrate using an adhesive die attach film and electrically connected via bonding wires. The MEMS die is connected to the interposer using flipchip bonding with conductive bumps formed on the interconnect structure of the MEMS die. The interposer is electrically connected to the substrate using conductive bumps. This packaging approach isolates the MEMS die from external stresses.

### RELATED APPLICATION

This application claims priority to U.S. Provisional Application For Patent No. 63/696,965, filed Sep. 20, 2024, the contents of which are incorporated by reference in their entirety.

### TECHNICAL FIELD

This disclosure relates generally to the field of microelectromechanical systems (MEMS) packaging and, more particularly, to a low-stress packaging approach for MEMS devices that utilizes a floating die configuration to isolate the MEMS device from mechanical and thermo-mechanical stresses.

### BACKGROUND

Micro-Electro-Mechanical Systems (MEMS) are miniaturized devices that combine mechanical and electrical components on a microscopic scale. MEMS devices are packaged for several reasons, such as to shield the delicate microstructures from environmental factors such as dust, moisture, and physical damage, to facilitate connection with other electronic components and systems, to create an environment that allows the MEMS device to function at its best, and to minimize external stresses that can affect the device's operation.

One of the primary concerns in MEMS packaging is the need for low-stress environments. MEMS dies are sensitive to mechanical stresses, which can significantly affect their performance and reliability. This sensitivity arises from the fact that MEMS devices often rely on precise mechanical movements or deformations to function, such as in accelerometers or pressure sensors. Even small amounts of external stress can interfere with these movements, leading to inaccurate measurements or device failure.

Traditional packaging methods often subject MEMS dies to various stress factors, including substrate bending and thermo-mechanical loading. The flexibility of package substrates can lead to bending, which transfers stress to the MEMS die. This bending can occur due to external forces or internal stresses built up during the manufacturing process. Additionally, temperature fluctuations can cause different materials in the package to expand or contract at different rates, inducing stress on the MEMS die. This thermal mismatch is particularly problematic in applications where the device experiences significant temperature variations during operation.

These stress factors can lead to performance drift, reduced sensitivity, or even failure of the MEMS device. Performance drift occurs when the device output changes over time due to accumulated stress, reducing its accuracy and reliability. Reduced sensitivity can result from stress-induced changes in the mechanical properties of the MEMS structures, affecting their ability to respond to the intended stimuli. In some cases, excessive stress can even cause physical damage to the delicate MEMS structures, leading to complete device failure.

Therefore, there is a need for packaging solutions that can effectively isolate MEMS dies from these stress sources while maintaining a compact form factor. The preferred package would create a stable, low-stress environment for the MEMS die while still allowing it to interact with its surroundings as intended. This is particularly challenging for devices that need to measure external phenomena, such as pressure sensors or microphones, which require some form of controlled exposure to the environment.

Previous attempts to address this issue have resulted in bulky packages or complex isolation mechanisms, which are not ideal for the shrinking dimensions of modern electronic devices. Some approaches have used thick, rigid substrates to minimize bending, but these increase the overall size of the package. Others have employed complex spring-like structures or elastomeric materials to absorb stress, but these can be difficult to manufacture consistently at scale.

The challenge lies in creating a packaging solution that provides effective stress isolation while also allowing for miniaturization and ease of integration. As such, further development is needed.

### SUMMARY

A microelectromechanical systems (MEMS) package includes a substrate having a first cavity. An interposer is mounted on the substrate. A MEMS die is attached to the interposer. The interposer is positioned such that the MEMS die extends into the first cavity of the substrate. A cap extends over the interposer and the MEMS die. The cap, in combination with the first cavity of the substrate, defines a second cavity enclosing the MEMS die. The MEMS die is configured to float within the second cavity. The second cavity contains a gas or is at a near vacuum state. The MEMS package may include an application-specific integrated circuit (ASIC) mounted on the substrate. The ASIC may be mechanically attached to the substrate using an adhesive die attach film and electrically connected to the substrate via bonding wires.

The MEMS package may include first conductive bumps electrically connecting the interposer to the substrate.

The MEMS package may include second conductive bumps electrically connecting the MEMS die to the interposer. The second conductive bumps may be formed on pads of an interconnect structure of the MEMS die.

The cap may be hermetically sealed to the substrate.

The cap may have a hole defined therein in a top surface thereof allowing interaction between the MEMS die and an external environment.

The cap may have a hole defined in a sidewall thereof allowing interaction between the MEMS die and an external environment.

The substrate may have a hole defined therein allowing interaction between the MEMS die and an external environment.

A method of manufacturing a microelectromechanical systems (MEMS) package includes providing a substrate having a first cavity. A MEMS die is attached to an interposer. The interposer is mounted on the substrate such that the MEMS die extends into the first cavity of the substrate. A cap is attached over the interposer and the MEMS die. The cap, in combination with the first cavity of the substrate, defines a second cavity enclosing the MEMS die. The MEMS die is configured to float within the second cavity. The second cavity contains a gas or is at a near vacuum state.

The method may include mounting an Application-Specific Integrated Circuit (ASIC) on the substrate. Mounting the ASIC may include mechanically attaching the ASIC to the substrate using an adhesive die attach film and electrically connecting the ASIC to the substrate via bonding wires.

Attaching the MEMS die to the interposer may include using flipchip bonding.

The method may include forming first conductive bumps to electrically connect the interposer to the substrate.

The method may include forming second conductive bumps to electrically connect the MEMS die to the interposer. The second conductive bumps may be formed on pads of an interconnect structure of the MEMS die.

The method may include electrically connecting the ASIC to the substrate via bonding wires.

Attaching the cap may include attaching the cap to the substrate using a suitable adhesive material.

The method may include forming a hole in a top surface of the cap to allow interaction between the MEMS die and an external environment.

The method may include forming a hole in a sidewall of the cap to allow interaction between the MEMS die and an external environment.

The method may include forming a hole in the substrate to allow interaction between the MEMS die and an external environment.

### BRIEF DESCRIPTION OF THE DRAWINGS

FIG. 1 is a cross-sectional view of a MEMS package according to an embodiment disclosed herein.

FIG. 2 is a cross-sectional view illustrating a first step in the manufacturing process of the MEMS package, showing the attachment of a MEMS die to an interposer.

FIG. 3 is a cross-sectional view illustrating a subsequent step in the manufacturing process, showing the mounting of the interposer with attached MEMS die onto a substrate with a cavity.

FIG. 4 is a cross-sectional view illustrating the second to final step in the manufacturing process, showing the attachment of a protective cap to complete the MEMS package assembly, with the final step being the placement of the cap as shown in FIG. 1.

FIG. 5 is a cross sectional view of a MEMS package according to another embodiment disclosed herein.

FIGS. 6-7 are cross-sectional views of a MEMS package according to other embodiments disclosed herein in which environmental access holes are present in various locations.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Referring to FIG. 1, a packaging approach for Micro-Electro-Mechanical Systems (MEMS) devices 10 is shown. A flipchip MEMS die 15 is attached to an interposer 14. This interposer 14 with the attached MEMS die 15 is mounted within a cavity 21 defined in a substrate 11. The interposer 14 serves as an intermediary between the MEMS die 15 and the main substrate 11, providing additional electrical routing and mechanical support for the MEMS die 15 while allowing for a degree of isolation from the main substrate. The use of a flipchip MEMS die 15 allows for a more compact design compared to traditional wire-bonded MEMS dies. This configuration enables direct electrical connections between pads on the die 15 and pads on the interposer 14, reducing the overall package size.

A cap 19 extends over the interposer 14 and MEMS die 15 to enclose and protect the package from external environmental factors. An air cavity 21 is maintained around the MEMS die 15, creating a floating effect. The air cavity 21 maintained around the MEMS die within the package allows for minor movements of the die without transferring stress from the package to the sensitive MEMS structures. The floating MEMS die 15 configuration effectively isolates the MEMS device 10 from mechanical and thermo-mechanical stresses commonly encountered in traditional packaging methods. This provides for stress-free movement of the MEMS die 15, enhancing performance and reliability.

Electrical connections between various components are facilitated by conductive bumps. Bumps 17 are positioned between pads on the interposer 14 and pads on the substrate 11, providing electrical pathways and mechanical connection between these two elements. Bumps 16 are located between pads on the MEMS die 15 and pads on the interposer 14, enabling the flipchip connection and electrical communication between the MEMS die and the interposer.

An Application-Specific Integrated Circuit (ASIC) 12 may be included on the substrate 11 for signal processing or other functions related to the MEMS device operation. The ASIC 12 is connected to the substrate 11 via bonding wires 13, which provide both electrical and mechanical connection. An adhesive die attach film layer provides mechanical attachment between the ASIC 12 and the substrate 11.

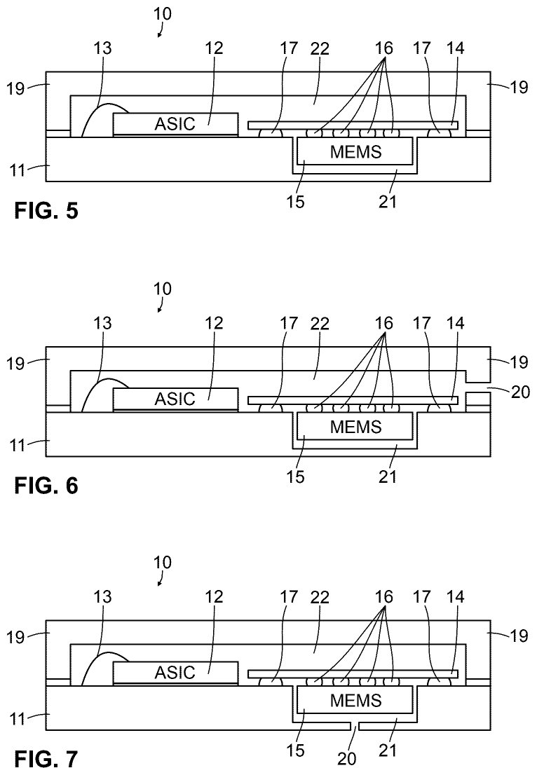

The protective cap 19 may optionally include a hole 20 formed therein. This hole 20 serves a specific purpose in certain MEMS applications where interaction with the external environment is necessary. For instance, in MEMS microphone or pressure sensor applications, the hole 20 allows sound waves or air pressure to reach the MEMS die 15, enabling the device to perform its sensing function. The cavity 22 is connected to cavity 21, allowing environmental interaction through the hole 20 to reach the MEMS die 15. The presence of the hole 20 does not compromise the overall protective nature of the cap 19, as it can be precisely sized and positioned to allow for the required environmental interaction while still shielding the MEMS die 15 from contaminants and mechanical interference. Note that the hole 20 is an optional feature and may not be present in all embodiments. The specific embodiment shown in FIG. 1 includes this hole 20 to illustrate its potential inclusion, but the packaging solution can be implemented without the hole for MEMS devices that do not require direct environmental exposure—for example, see FIG. 5, in which the cap 19 lacks the hole 20.

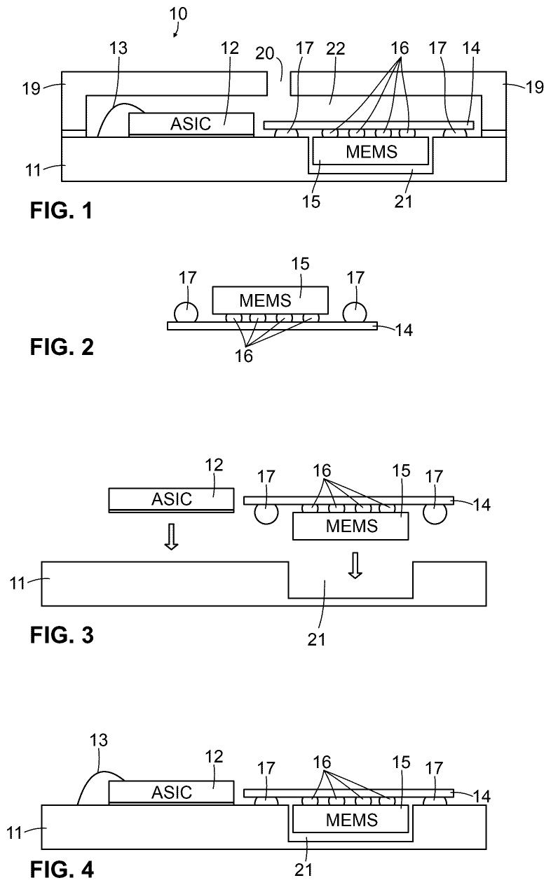

The manufacturing process for this packaging approach is illustrated in FIGS. 2-4. Referring to FIG. 2, the process begins with the preparation of the MEMS die 15. The MEMS die 15 is attached to the interposer 14 using flipchip bonding techniques. Conductive bumps 16 are formed on pads of the interconnect (BEOL) structure for the MEMS die 15, allowing for electrical and mechanical connection to pads of the interposer 14. The interposer 14 serves as a substrate for the MEMS die 15 and provides additional routing capabilities.

Moving to FIG. 3, the next step in the process is shown. A substrate 11 is prepared with a cavity 21 sized to accommodate the die 15, with the interposer 14 supported by peripheral sides of the substrate surrounding the cavity 21. The cavity 21 provides the space utilized for the floating configuration of the MEMS die 15. Separately, an application-specific integrated circuit (ASIC) 12 is prepared for integration into the package. The ASIC 12 is attached to the substrate 11 using an adhesive die attach film, providing mechanical connection. Electrical connections are made using bonding wires between pads of the ASIC die and pads of the substrate 11.

The interposer 14 with the attached MEMS die 15 is then mounted onto the substrate 11. Conductive bumps 17 are used to create electrical connections between pads of the interposer 14 and pads of the substrate 11. These bumps 17 also provide mechanical support for the interposer 14 while maintaining a gap that forms part of the air cavity 21 around the MEMS die 15.

Finally, as illustrated in FIG. 4, the protective cap 19 is attached to complete the package assembly. The cap 19 extends over the interposer 14 and MEMS die 15, attaching to the substrate 11 at its edges using, for example, a suitable adhesive material. This step seals the package, providing protection from external environmental factors. The cap 19 is carefully aligned to avoid stressing the interposer 14, which could transmit stress to the MEMS die 15. The alignment of the interposer 14 when mounted ensures the MEMS die 15 is not stressed, maintaining the air cavity 21 around the MEMS die 15 and allowing for stress-free movement of the die.

The cavity 21 creates the floating effect, allowing the MEMS die 15 to be isolated from mechanical and thermo-mechanical stresses that may be present in the substrate 11 or introduced by external forces.

The resulting package 10 effectively isolates the sensitive MEMS structures within the die 15 from external stresses while maintaining necessary electrical connections through the interposer 14 and substrate 11. The ASIC 12 on the substrate 11 can perform signal processing or other functions related to the MEMS device operation, with electrical pathways provided through the various conductive bump connections 16 and 17 in the assembly, as well as the bonding wires connecting the ASIC 12 to the substrate 11.

It is evident that modifications and variations can be made to what has been described and illustrated herein without departing from the scope of this disclosure. For example, the second cavity 22 surrounding the MEMS die 15 can be filled with various substances to optimize the performance and longevity of the MEMS device. In the embodiment described hereinabove, this cavity contains air, allowing for typical operation in ambient conditions. However, in alternative embodiments, the cavity may be filled with other gases or maintained at a near vacuum state. For instance, an inert gas such as nitrogen or argon may be used to prevent oxidation or other chemical reactions that could degrade the MEMS components over time. In applications involving minimal damping of the MEMS movement, a near vacuum state may be preferable. The choice of cavity environment depends on the specific MEMS function, operating conditions, and longevity requirements. When the optional hole 20 in the cap 19 is not present, the cavities 21 and 22 can be sealed (e.g., hermetically sealed) by the cap 19, allowing for precise control over the internal environment. This sealed configuration enables the maintenance of a specific gas composition or near vacuum state.

As yet another variation, the optional hole 20 may be formed in the sidewall of the cap 19, and the cross-sectional shape of the optional hole 20 may be cylindrical. This configuration is shown in FIG. 6. As yet another variation, the optional hole 20 may be formed in the substrate 11 below the MEMS die 15 (e.g., the surface of the cavity 21 facing the MEMS die 15), and the cross-sectional shape of the optional hole 20 may be cylindrical.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A microelectromechanical systems (MEMS) package, comprising:
a substrate having a first cavity;
an interposer mounted on the substrate;
a MEMS die attached to the interposer, wherein the interposer is positioned such that the MEMS die extends into the first cavity of the substrate; and
a cap extending over the interposer and the MEMS die, wherein the cap, in combination with the first cavity of the substrate, defines a second cavity enclosing the mems die, and wherein the mems die is configured to float within the second cavity.

2. The MEMS package of claim 1, wherein the second cavity contains a gas.

3. The MEMS package of claim 1, wherein the second cavity is at a near vacuum state.

4. The MEMS package of claim 1, further comprising an application-specific integrated circuit (ASIC) mounted on the substrate, wherein the ASIC is mechanically attached to the substrate using an adhesive die attach film and electrically connected to the substrate via bonding wires.

5. The MEMS package of claim 1, further comprising first conductive bumps electrically connecting the interposer to the substrate.

6. The MEMS package of claim 5, further comprising second conductive bumps electrically connecting the mems die to the interposer, wherein the second conductive bumps are formed on pads of an interconnect structure of the MEMS die.

7. The MEMS package of claim 1, wherein the cap is hermetically sealed to the substrate.

8. The MEMS package of claim 1, wherein the cap has a hole defined in a top surface thereof allowing interaction between the MEMS die and an external environment.

9. The MEMS package of claim 1, wherein the cap has a hole defined in a sidewall thereof allowing interaction between the MEMS die and an external environment.

10. The MEMS package of claim 1, wherein the substrate a hole defined therein allowing interaction between the MEMS die and an external environment.

11. A method of manufacturing a microelectromechanical systems (MEMS) package, the method comprising:
providing a substrate having a first cavity;
attaching a MEMS die to an interposer;
mounting the interposer on the substrate such that the MEMS die extends into the first cavity of the substrate; and
attaching a cap over the interposer and the MEMS die, wherein the cap, in combination with the first cavity of the substrate, defines a second cavity enclosing the MEMS die, and wherein the MEMS die is configured to float within the second cavity, the second cavity containing a gas or being at a near vacuum state.

12. The method of claim 11, further comprising mounting an Application-Specific Integrated Circuit (ASIC) on the substrate, wherein mounting the ASIC comprises mechanically attaching the ASIC to the substrate using an adhesive die attach film and electrically connecting the ASIC to the substrate via bonding wires.

13. The method of claim 11, wherein attaching the MEMS die to the interposer comprises using flipchip bonding.

14. The method of claim 11, further comprising forming first conductive bumps to electrically connect the interposer to the substrate.

15. The method of claim 14, further comprising forming second conductive bumps to electrically connect the MEMS die to the interposer, wherein the second conductive bumps are formed on pads of an interconnect structure of the mems die.

16. The method of claim 11, further comprising electrically connecting the ASIC to the substrate via bonding wires.

17. The method of claim 11, wherein attaching the cap comprises attaching the cap to the substrate using a suitable adhesive material.

18. The method of claim 11, further comprising forming a hole in a top surface of the cap to allow interaction between the MEMS die and an external environment.

19. The method of claim 11, further comprising forming a hole in a sidewall of the cap to allow interaction between the MEMS die and an external environment.

20. The method of claim 11, further comprising forming a hole in the substrate to allow interaction between the MEMS die and an external environment.
